(19) United States
(12) Patent Application Publication
(10) Pub. No.: US 2025/0089452 A1
(43) Pub. Date: Mar. 13, 2025

(54) DISPLAY PANEL AND ELECTRONIC DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Liang MA, Wuhan, Hubei (CN)

(21) Appl. No.: 18/548,451

(22) PCT Filed: Jun. 30, 2023
(86) PCT No.: PCT/CN2023/104690

§ 371 Date: Aug. 30, 2023

(30) Foreign Application Priority Data
Jun. 15, 2023 (CN) 202310715969.6

(51) Int. Cl. H10K 59/121; H10K 59/131; H10K 59/35

(52) U.S. Cl. CPC H10K 59/121; H10K 59/131; H10K 59/353

(57) ABSTRACT

The present application provides a display panel and an electronic device, wherein pixels of a first display area of the display panel is less than pixels of a second display area of the display panel, so that the light transmittance of the first display area is greater than the light transmittance of the second display area, the light-transmitting area of the first display area can be increased, the diffraction peak intensity can be reduced, and the imaging quality can be improved. The technical problem that the imaging quality is reduced due to visible lights being diffracted by the area for the camera under panel is alleviated.

### TECHNICAL FIELD

The present application relates to the technical field of display technologies, in particular to a display panel and an electronic device.

### BACKGROUND

With increasing demand for screens of mobile phones, full screens have become an inevitable trend. However, some internal components, such as a front-facing camera and a face recognition sensor of a mobile phone, occupy a display area of a screen, resulting in a loss in displaying pictures and a failure in realizing full screens. The technology of camera under panel (CUP) alleviates this problem, since no hole is required on an area for the CUP, and the area for the CUP can transmit lights and display images. However, the area for the CUP has a non-transmit area such as an anode, and therefore visible lights are diffracted by the non-transmit area, thereby reducing imaging quality.

### Technical Solution

The present application provides a display panel and an electronic device to alleviate the currently technical problem that the imaging quality is reduced due to visible lights being diffracted by the area for the camera under panel.

To solve the above problems, the following technical solution is provided by the present application.

An embodiment of the present application provides a display panel. The display panel includes a first display area and a second display area at the periphery of the first display area, the light transmittance of the first display area is greater than that of the second display area;
the first display area includes a plurality of first pixel areas and a plurality of pixel blank areas, the first pixel area and each of the pixel blank areas are alternately arranged in a first direction, and the first pixel area and each of the pixel blank areas are alternately arranged in a second direction, the first direction and the second direction are different;
the second display area includes a plurality of sub-pixels arranged in an array, the plurality of sub-pixels includes a plurality of sub-pixel rows arranged in the first direction and a plurality of sub-pixel columns arranged in the second direction;
wherein, in the first direction, the first pixel area overlaps two adjacent sub-pixel rows; In the second direction, the first pixel area overlaps three adjacent sub-pixel columns.

In an embodiment, in the second display area, the plurality of sub-pixels includes a plurality of first sub-pixels of a first color, second sub-pixels of a second color, and third sub-pixels of a third color;
the first sub-pixel and the second sub-pixel are alternately arranged in the first direction to define a plurality of first rows, the third sub-pixel is arranged to define a plurality of second rows in the first direction, a plurality of sub-pixel rows include the first rows and the second rows alternately arranged;
the first sub-pixel and the second sub-pixel are alternately arranged in the second direction to define a plurality of first columns, and the third sub-pixels is arranged in the second direction to define a plurality of second columns, a plurality of sub-pixel columns includes the first columns and the second columns alternately arranged;
wherein, in the first direction, the first pixel area overlaps one first row and one second row adjacent;
in the second direction, the first pixel area overlaps one first columns and two second columns adjacent, or the first pixel area overlaps one second columns and two first columns adjacent.

In an embodiment of the present application, in the first display area, the first pixel area includes a fourth sub-pixel of a first color, a fifth sub-pixel of a second color, and a sixth sub-pixel of a third color;
wherein the area of the fourth sub-pixel is greater than the area of the first sub-pixel, the area of the fifth sub-pixel is greater than the area of the second sub-pixel, and the area of the sixth sub-pixel is greater than the area of the third sub-pixel.

In an embodiment of the present application, in the first direction, the fourth sub-pixel overlaps one first row and one second row adjacent, the fifth sub-pixel overlaps one of the first row or the second row, the sixth sub-pixel overlaps the other one of the first row or the second row;
in the second direction, the fourth sub-pixel overlaps one first column and one second column adjacent, the fifth sub-pixel overlaps one first column and one second column adjacent, and the sixth sub-pixel overlaps one first column and one second column adjacent.

In an embodiment of the present application, in the first display area, the fourth sub-pixel is arranged in the second direction to define a plurality of third columns, and the fifth sub-pixel and the sixth sub-pixel are alternately arranged in the second direction to define a plurality of fourth columns;
in the second direction, one third column overlaps one first column and one second column adjacent, one fourth column overlaps one first column and one second column adjacent;
in the second direction, one third column and one fourth column adjacent are overlapped with one first column and two second columns adjacent, or are overlapped with one second column and two first columns adjacent.

In an embodiment of the display panel in the present application, the adjacent third column and the fourth column share one data line with the corresponding one first column and two second columns adjacent, or share one data line with the corresponding one second column and the two first columns adjacent.

In an embodiment of the display panel in the present application, the fourth sub-pixel of the third column shares one data line with the first sub-pixel and the second sub-pixel of one of two adjacent first columns, the fifth sub-pixel of the fourth column shares one data line with the first sub-pixel and the second sub-pixel of the other column of two adjacent first columns, and the sixth sub-pixel of the fourth column shares one data line with the third sub-pixel of the second column.

In an embodiment of the display panel in the present application, the fourth sub-pixel of the third column shares one data line with the third sub-pixel of on of two adjacent second columns, the fifth sub-pixel of the fourth column shares one data line with the first sub-pixel and the second sub-pixel of the first column, and the sixth sub-pixel of each of the fourth columns shares one data line with each of the third sub-pixels of another one of the two adjacent second columns.

In an embodiment of the display panel in the present application, in the first direction, one fourth sub-pixel overlaps one fifth sub-pixel and one sixth sub-pixel adjacent.

In the display panel provided in the embodiment of the present application, the fourth sub-pixel includes a first sub-block and a second sub-block, the first sub-block and the second sub-block are spaced in the second direction, and the first sub-block and the second sub-block are connected by a first transparent wire.

In an embodiment of the display panel in the present application, a shape of at least one of the fourth sub-pixel, the fifth sub-pixel, and the sixth sub-pixel is a polygon, and a corner of the polygon is rounded.

In an embodiment of the display panel in the present application, the first color is blue, the third color is green, and the second color is red.

An embodiment of the present application also provides an electronic device includes a housing and a display panel of one of the foregoing embodiments, the display panel is mounted in the housing.

### Beneficial Effect

According to the display panel provided in the present application, the pixel blank area is provided in the first display area so that the light transmittance of the first display area is greater than the light transmittance of the second display area, thereby increasing the light-transmitting area of the first display area, reducing the diffraction peak intensity, and further improving the imaging quality. As such, the currently technical problem, which the imaging quality is reduced due to visible lights being diffracted by the area for the camera under panel, is alleviated.

### BRIEF DESCRIPTION OF THE DRAWINGS

In order to describe the embodiments or the technical solutions in the existing art more clearly, the following briefly describes the drawings required for describing the embodiments or the existing art. It should be understood that the drawings in the following description are merely for some embodiments of the present application. For those of skill in the art, other drawings can be obtained from these drawings without creative efforts.

FIG. 1 is a schematic diagram of a top view of a display panel provided in an embodiment of the present application.

FIG. 2 is a detailed structural diagram of a first display area and a second display area provided in an embodiment of the present application.

FIG. 3 is a schematic diagram of a data line shared by a first display area and a second display area provided in an embodiment of the present application.

FIG. 4 is a simulation diagram of comparison on diffraction peak intensity provided in an embodiment of the present application.

FIG. 5 is a detailed structural diagram of a first pixel area provided in an embodiment of the present application.

FIG. 6 is a simulation diagram of the diffraction peak intensity corresponding to the first pixel area in FIG. 5.

FIG. 7 is another detailed structure diagram of a first pixel area provided in an embodiment of the present application.

FIG. 8 is a simulation diagram of the diffraction peak intensity corresponding to the first pixel area in FIG. 7.

### DETAILED DESCRIPTION OF THE EMBODIMENTS

The following description of the embodiments is provided with reference to drawings to illustrate embodiments that the present application can be implemented. The terms mentioned in the present application, for example, “up”, “under”, “front”, “rear”, “left”, “right”, “in”, “out”, “side”, and the like, are merely referring to the orientation in the drawings. Therefore, the directional terms are used to explain and understand the present application, instead of limiting the present application. In the drawings, components having similar structures are denoted by the same reference numerals. In the drawings, the thickness of some layers and areas is enlarged for clear understanding and easy description. That is, the size and thickness of the component shown in the drawings are not showed in a fixed ratio, but the present application is not limited thereto.

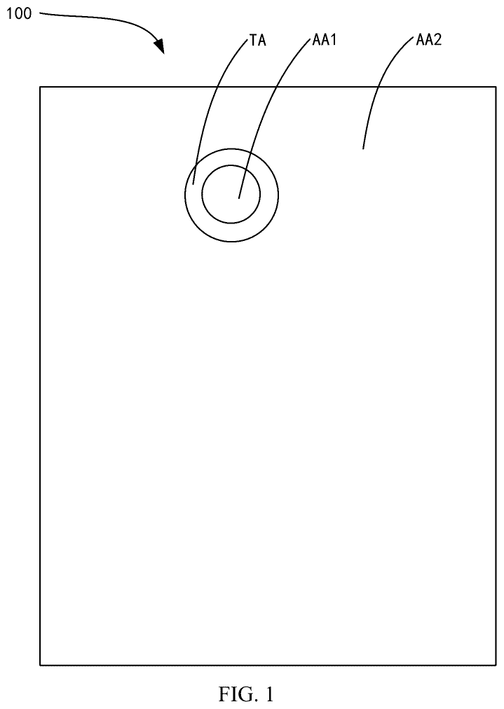

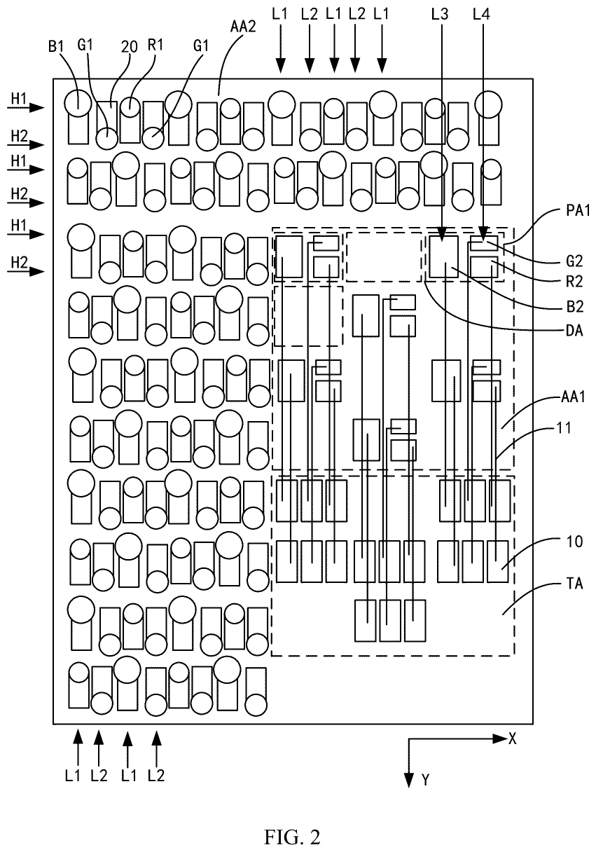

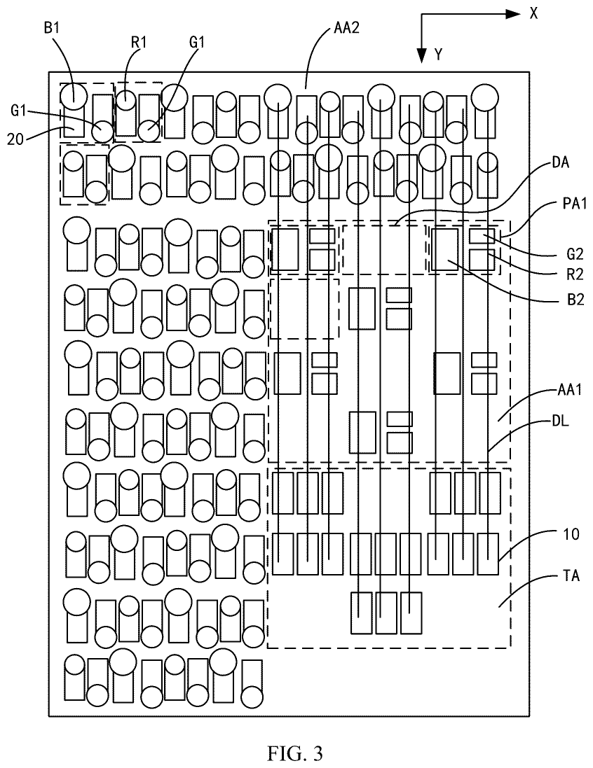

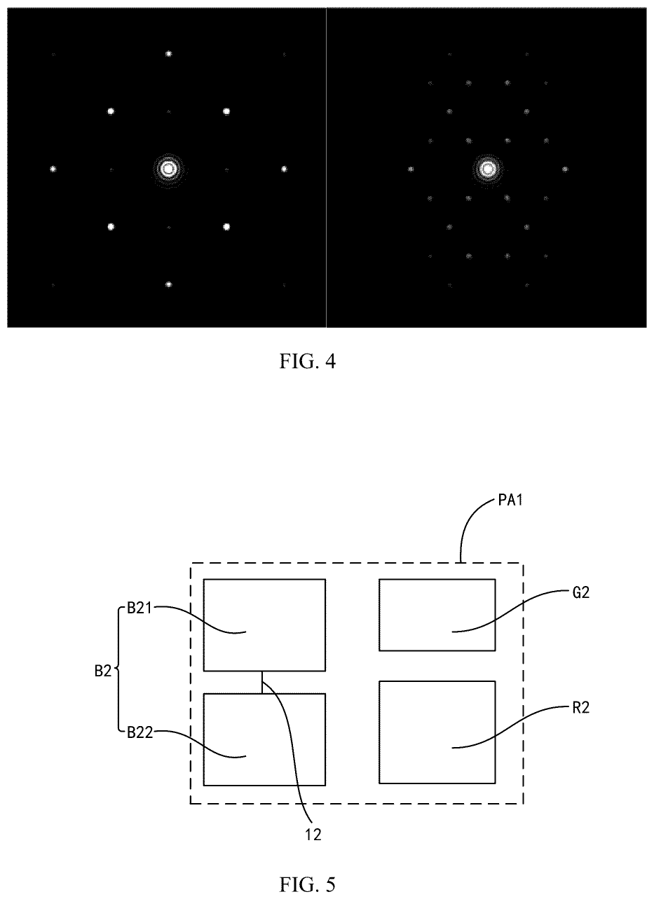

Referring to FIG. 1 to FIG. 4, FIG. 1 is a schematic diagram of a top view structure of a display panel provided in an embodiment of the present, FIG. 2 is a schematic diagram of a detailed structure of a first display area and a second display area provided in an embodiment of the present, FIG. 3 is a schematic diagram of a data line shared by the first display area and the second display area provided in an embodiment of the present, FIG. 4 is a schematic diagram of diffraction peak intensity comparison simulation provided in an embodiment of the present. As shown in FIG. 1, the display panel 100 includes a first display area AA1, a second display area AA2 at the periphery of the first display area AA1, and a transition area TA between the first display area AA1 and the second display area AA2. In addition to the display function, the first display area AA1 can realize functions such as fingerprint recognition and photography. Embodiments of the present application are described based on the function of photography of the first display area AA1.

The pixels of the first display area AA1 are denser than the pixels of the second display area AA2, so that the light transmittance of the first display area AA1 is greater than the light transmittance of the second display area AA2. The density of the pixels refers to the number of pixels disposed a unit area. By providing the pixels of the first display area AA1 denser than the second display area AA2, the light-transmitting area of the first display area AA1 can be increased, the diffraction peak intensity can be reduced, and the imaging quality can be further improved. As such, the currently technical problem, which the imaging quality is reduced due to visible lights being diffracted by the area for the camera under panel, is alleviated.

The following is provided to explain in detail how to achieve the pixels of the first display area AA1 that are less dense than that of the second display area AA2.

Specifically, the first display area AA1 includes a plurality of first pixel areas PA1 and a plurality of pixel blank areas DA. Each of the first pixel areas PA1 and each of the pixel blank areas DA are alternately arranged in a first direction X, and the first pixel area PA1 and the pixel blank area DA are also alternately arranged in a second direction Y. The first direction X and the second direction Y are different, for example, the first direction X is a horizontal direction, the second direction Y is a vertical direction, and the first direction X and the second direction Y are perpendicular to each other. The first pixel area PA1 is provided with pixels for display, the pixel blank area DA refers to an area where no pixels are provided, and the pixel blank area DA has high transparency.

The second display area AA2 includes a plurality of sub-pixels arranged in an array. The plurality of sub-pixels include a plurality of sub-pixel rows arranged in the first direction X and a plurality of sub-pixel columns arranged in the second direction Y. In the first direction X, the first pixel area PA1 overlaps two adjacent sub-pixel rows; and in the second direction Y, the first pixel area PA1 overlaps three adjacent sub-pixel columns.

It should be noted that, in this embodiment, the two adjacent sub-pixel rows extend through the corresponding first pixel area PA1 in the first direction X, so that the two adjacent sub-pixel rows and the corresponding first pixel area PA1 are overlapped in the first direction X. the three adjacent sub-pixel columns extend through the corresponding first pixel area PA1 in the second direction Y, so that the three adjacent sub-pixel columns and the corresponding first pixel area PA1 are arranged to overlap in the second direction Y. That is, in the first direction X, the width of the first pixel area PA1 is at least greater than or equal to the widths of the two adjacent sub-pixel rows; and in the second direction Y, the width of the first pixel area PA1 is at least greater than or equal to the widths of the three adjacent sub-pixel columns.

In an embodiment, the arrangement of the pixels of the first display area AA1 is different from the arrangement of the pixels of the second display area AA2. The arrangement of the pixels of the first display area AA1 is a standard type arrangement for RGB pixels, and the arrangement of the pixels of the second display area AA2 is a Pentile type arrangement for pixels.

Specifically, in the second display area AA2, the plurality of sub-pixels includes a plurality of first sub-pixels B1 of first color, second sub-pixels R1 of the second color, and third sub-pixels G1 of the third color. In a case that the first color is blue, the second color is red, and the third color is green, the first sub-pixels B1 are the blue sub-pixels, the second sub-pixels R1 are the red sub-pixels, and the third sub-pixels G1 are the green sub-pixels.

Each of the first sub-pixels B1 and each of the second sub-pixels R1 are alternately arranged in the first direction X to define a first row H1, and a plurality of first rows H1 is provided. The third sub-pixels G1 are arranged in the first direction X to define a second row H2, and a plurality of second rows H2 is provided. The plurality of sub-pixel rows includes the first rows H1 and the second rows H2 alternately arranged. Each of the first sub-pixels B1 and each of the second sub-pixels R1 are alternately arranged in the second direction Y, and a plurality of first columns L1 is provided, and the third sub-pixel G1 is arranged in the second direction Y, and a plurality of second columns L2 is provided. The plurality of sub-pixel columns includes the first columns L1 and the second columns L2 alternately arranged.

In the adjacent first column L1 and the second column L2, the first sub-pixel B1 and the second sub-pixel R1 adjacent in the first column L1 share the third sub-pixel G1 in the second column L2, and the third sub-pixel G1 in the second column L2 share the first sub-pixel B1 and the second sub-pixel R1 adjacent in the first column L1, to define the Pentile type arrangement for pixels.

In the first direction X, the first pixel area PA1 overlaps one first row H1 and one adjacent second row H2. In the second direction Y, the first pixel area PA1 overlaps one first columns L1 and two second columns L2 adjacent to the one first row H1, or the first pixel area PA1 overlaps one second column L2 and two first columns L1 adjacent to the one second column L2. Specifically, one first row H1 and one adjacent second row H2 extend in the first direction X through the corresponding first pixel area PA1, so that the one first row H1 and the one adjacent second row H2 are arranged to overlap in the first direction X. One first column L1 and two second columns L2 adjacent the one first column L1 extend in the second direction Y through the corresponding first pixel area PA1, so that the one first column L1 and the two second columns L2 are overlapped in the second direction Y. One second column L2 and two first columns L1 adjacent the one second column L2 extend in the second direction Y through the corresponding first pixel area PA1, so that the one second column L2 and the two first columns L1 and the corresponding first pixel area PA1 are overlapped in the second direction Y. That is, in the first direction X, the width of the first pixel area PA1 is at least greater than or equal to the widths of two adjacent first and second rows H1 and H2. In the second direction Y, the width of the first pixel area PA1 is at least equal to or greater than the widths of one first column L1 and two second columns L2 adjacent the one first column L1 adjacent first and second columns L1 and L2. Moreover, in the second direction Y, the width of the first pixel area PA1 is at least equal to or greater than the widths of one second column L2 and two first columns L1 adjacent the one second column L2.

In the first display area AA1, the first pixel area PA1 includes a fourth sub-pixel B2 of first color, a fifth sub-pixel R2 of second color, and a sixth sub-pixel G2 of third color. That is, the fourth sub-pixel B2 is a blue sub-pixel, the fifth sub-pixel R2 is a red sub-pixel, and the sixth sub-pixel G2 is a green sub-pixel. The area of the fourth sub-pixel B2 is greater than the area of the first sub-pixel B1, the area of the fifth sub-pixel R2 is greater than the area of the second sub-pixel R1, and the area of the sixth sub-pixel G2 is greater than the area of the third sub-pixel G1. In the first direction X, one fourth sub-pixel B2 overlaps one fifth sub-pixels R2 and one sixth sub-pixels G2 adjacent to the one fourth sub-pixel B2, that is, one fifth sub-pixel R2 and one sixth sub-pixel G2 adjacent to the one fourth sub-pixel B2 are extended in the first direction X through the one fourth sub-pixel B2, so that one fifth sub-pixel R2 and one sixth sub-pixel G2 adjacent to the one fourth sub-pixel B2 are overlapped with the one fourth sub-pixel B2 in the first direction X. That is, in the first direction X, the width of the fourth sub-pixel B2 is at least greater than or equal to the widths of one fifth sub-pixel R2 and one sixth sub-pixel G2 adjacent to the one fourth sub-pixel B2.

The fifth sub-pixel R2 and the sixth sub-pixel G2 are spaced apart in the second direction Y, and the fourth sub-pixel B2 and the fifth sub-pixel R2 are spaced apart in the first direction X, to define a standard RGB type arrangement for pixels. The area of the fourth sub-pixel B2 is greater than the area of the fifth sub-pixel R2 and the area of the sixth sub-pixel G2.

In the first direction X, the fourth sub-pixel B2 overlaps one first row H1 and one second row H2 adjacent to the one first row H1, the fifth sub-pixel R2 overlaps one of the first row H1 and the second row H2 adjacent, and the sixth sub-pixel G2 overlaps the other one of the first row H1 or the second row H2 adjacent. Specifically, one first rows H1 and one adjacent second rows H2 extend in the first direction X through the corresponding fourth sub-pixel B2, so that the one first rows H1 and the one adjacent second rows H2 are overlapped with the corresponding fourth sub-pixel B2 in the first direction X. One of the first row H1 and the second row H2 adjacent is extended in the first direction X through the corresponding fifth sub-pixel R2, so that the one of the first row H1 and the second row H2 adjacent is overlapped with the corresponding fifth sub-pixel R2 in the first direction X. The other one of the first row H1 and the second row H2 adjacent is extended in the first direction X through the corresponding sixth sub-pixels G2, so that the one of the first row H1 and the second row H2 adjacent is overlapped with the corresponding sixth sub-pixels G2 in the first direction X. That is, in the first direction X, the width of the fourth sub-pixel B2 is at least greater than or equal to the widths of the one first row H1 and one second row H2 adjacent to the one first row H1, the width of the fifth sub-pixel R2 is at least greater than or equal to the width of one of the first row H1 and the second row H2, and the width of the sixth sub-pixel G2 is at least greater than or equal to the width the other one of the first row H1 and the second row H2. Thus, in the first direction X, each of the first pixel areas PA1 corresponds to two sub-pixel rows of the second display area AA2, so that two sub-pixel rows in the second display area AA2 share two scanning lines with the sub-pixels in the first pixel area PA, thereby saving wiring.

In the second direction Y, the fourth sub-pixel B2 overlaps one first column L1 and one second column L2 adjacent to the one first column L1, the fifth sub-pixel R2 overlaps one first column L1 and one second column L2 adjacent to the one first column L1, and the sixth sub-pixel G2 overlaps one first column L1 and one second column L2 adjacent to the one first column L1. Specifically, one first column L1 and one second column L2 adjacent extend in the second direction Y through the corresponding fourth sub-pixels B2, so that one first column L1 and one second column L2 adjacent are overlapped with the corresponding fourth sub-pixels B2 in the second direction Y. One first column L1 and one second column L2 adjacent to the one first column L1 extend in the second direction Y through the corresponding fifth sub-pixels R2, so that the one first column L1 and the one second column L2 adjacent to the one first column L1 are overlapped in the second direction Y. One first column L1 and one second column L2 adjacent to the one first column L1 extend in the second direction Y through the corresponding sixth sub-pixels G2, so that the one first column L1 and the one second column L2 adjacent to the one first column L1 are overlapped in the second direction Y. That is, in the second direction Y, the width of the fourth sub-pixel B2 is at least larger than the width of the first column L1 or the second column L2, the width of the fifth sub-pixel R2 is at least larger than the width of the first column L1 or the second column L2, and the width of the sixth sub-pixel G2 is at least larger than the width of the first column L1 or the second column L2.

Further, in the first display area AA1, the fourth sub-pixels B2 are arranged in the second direction Y to define a third column L3, and a plurality of third columns L3 is provided. Each of the fifth sub-pixels R2 and each of the sixth sub-pixels G2 are alternately arranged in the second direction Y to define a fourth column L4, and a plurality of fourth columns L4 is provided. In the second direction Y, one third column L3 overlaps one first column L1 and one second column L2 adjacent to the one first column L1, and one fourth column L4 overlaps one first column L1 and one second column L2 adjacent to the one first column L1. Specifically, when the one first column L1 and the second column L2 adjacent to the one first column L1 extend in the second direction Y through the corresponding third columns L3, so the one first column L1 and the second column L2 adjacent to the one first column L1 are overlapped in the second direction Y with. One first column L1 and one second column L2 adjacent to the one first column L1 extend in the second direction Y through the corresponding fourth columns L4, so that the one first column L1 and the one second column L2 adjacent to the one first column L1 are arranged to overlap in the second direction Y. That is, in the second direction Y, the width of the third column L3 is at least larger than the width of the first column L1 or the second column L2, and the width of the fourth column L4 is at least larger than the width of the first column L1 or the second column L2.

Further, in the second direction Y, one third column L3 and one fourth column L4 adjacent the one third column L3 are overlapped with one first column L1 and two second columns L2 adjacent to the one first column L1, or are overlapped with one second column L2 and two first columns L1 adjacent to the one second column L2. Specifically, when one first column L1 and two second columns L2 adjacent to the one first column L1 extend in the second direction through one corresponding third column L3 and one fourth column L4, so that the one first column L1 and the two second columns L2 adjacent to the one first column L1 are overlapped with one corresponding third column L3 and one fourth column L4 in the second direction Y. Alternatively, one second column L2 and two first columns L1 adjacent to the one second column L2 extend in the second direction Y through one corresponding third column L3 and one fourth columns L4, so that the one second column L2 and the two first columns L1 adjacent to the one second column L2 are overlapped with the one corresponding third column L3 and one fourth columns L4 in the second direction Y. That is, in the second direction Y, the width of two adjacent third column L3 and fourth column L4 is at least greater than or equal to the width of one first columns L1 and two second columns L2 adjacent to the one first columns L1, or at least greater than or equal to the width of one second columns L2 and two first columns L1 adjacent to the one second columns L2.

Further, the third column L3 and the fourth column L4 adjacent share a data line DL with one corresponding first column L1 and two second columns L2 adjacent to the corresponding first column L1, or share a data line DL with one corresponding second column L2 and two first columns L1 adjacent to the corresponding second column L2. That is, in the second direction Y, each of the first pixel areas PA1 corresponds to three sub-pixel columns in the second display area AA2, and each sub-pixel column in the second display area AA2 corresponds to one data line DL. In this way, the sub-pixels in the first pixel area PA1 can share three data lines DL with three sub-pixel columns in the second display area AA2, so as to realize the display function of the first display area AA1 and save wiring.

The following provides a detailed explanation of sharing a data line DLDL by the sub pixels in the first pixel area PA1 and the sub pixels in the second display.

Referring to FIG. 3, the fourth sub-pixel B2 of the third column L3 shares one data line DL with the first sub-pixel B1 and the second sub-pixel R1 of one of two adjacent columns L1, the fifth sub-pixel R2 of the fourth column L4 shares one data line DL with the first sub-pixel B1 and the second sub-pixel R1 of the other one of the two adjacent first columns L1, and the sixth sub-pixel G2 of the fourth column L4 shares one data line DL with the third sub-pixel G1 of the second column L2.

The fourth sub-pixel B2 of the third column L3 shares one data line DL with the third sub-pixel G1 of one of two adjacent second columns L2, the fifth sub-pixel R2 of the fourth column L4 shares one data line DL with the first sub-pixel B1 and the second sub-pixel R1 of the first column L1, and the sixth sub-pixel G2 of the fourth column L4 shares one data line DL with the third sub-pixel G1 of the other one of the two adjacent second columns L2.

Further, in the first direction X, the pixel blank area DA overlaps at least one sub-pixel row of the second display area AA2, and/or in the second direction Y, the pixel blank area DA overlaps at least one sub-pixel column of the second display area AA2. Alternatively, in the first direction X, each pixel blank area DA overlaps two adjacent sub-pixel rows; and in the second direction Y, each pixel blank area DA overlaps three adjacent sub-pixel columns. For the arrangement and the overlapped relationship of the pixel blank area DA with the sub-pixel rows and the sub-pixel columns in the second display area AA2, reference may be made to the description of the arrangement and the overlapped relationship of the first pixel area PA1 with the sub-pixel row and the sub-pixel column in the second display area AA2, and details are not described herein again.

Specifically, in the first direction X, the pixel blank DA overlaps one first row H1 and one second row H2 adjacent to the one first row H1. In the second direction Y, the pixel blank area DA overlaps one first column L1 and two second columns L2, adjacent to the one first column L1, or the pixel blank area DA overlaps one second column L2 and two first columns L1 adjacent to the one second column L2. That is, each pixel blank area DA in the first display area AA1 corresponds to three sub-pixel columns of the second display area AA2, and each the first pixel area PA1 in the first display area AA1 also corresponds to three sub-pixel columns of the second display area AA2. As described above, in the same unit area, the number of pixels in the first display area AA1 is less than the number of pixels in the second display area AA2, so that the pixel density of the first display area AA1 is denser than the pixel density of the second display area AA2.

In order to further increase the light-transmitting area of the first display area AA1, a driving circuit corresponding to the sub-pixels of the first display area AA1 is provided in a transition area TA, as shown in FIG. 2. Specifically, a first driving circuit 10 is provided in the transition area TA, the first driving circuit 10 is connected to sub-pixels in the first pixel area PA1 through second transparent wires 11, and each first driving circuit 10 is correspondingly connected to one sub-pixel in the first pixel area PA1. A second driving circuit 20 for driving the sub-pixels in the second display area AA2 is provided correspondingly to the corresponding sub-pixels. Each second drive circuit 20 is also connected to one corresponding sub-pixel.

In this embodiment, by providing the pixel blank area DA in the first display area AA1, each pixel blank area DA corresponds to three sub-pixel columns of the second display area AA2, and each first pixel area PA1 in the first display area AA1 also corresponds to three sub-pixel columns of the second display area AA2, so that the pixel density of the first display area AA1 is less than the pixel density of the second display area AA2. As such, the light transmittance of the first display area AA1 is greater than the light transmittance of the second display area AA2, thereby increasing the light-transmitting area of the first display area AA1 and reducing the diffraction peak intensity. As shown in FIG. 4, the left view in FIG. 4 is a simulation diagram of the diffraction peak intensity of the under panel camera area in the prior art, and the right view in FIG. 4 is a simulation diagram of the diffraction peak intensity of the first display area AA1 with the pixel blank area DA in the first display area AA1. It can be clearly seen from FIG. 4 that the diffraction peak intensity of the embodiment of the present application is obviously reduced, thereby improving the imaging quality of the first display area AA1, and alleviating the currently technical problem that the imaging quality is reduced due to visible lights being diffracted by the area for the camera under panel.

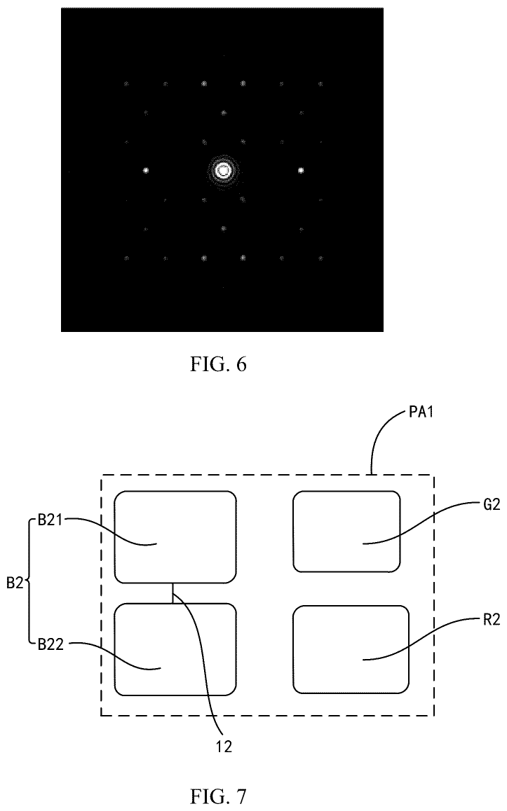

In an embodiment, referring to FIG. 1 to FIG. 6, FIG. 5 is a detailed structure diagram of a first pixel area provided in an embodiment of the present application, and FIG. 6 is a simulation diagram of diffraction peak intensity corresponding to the first pixel area in FIG. 5. Different from the above-described embodiment, in the first pixel area PA1, the fourth sub-pixel B2 includes a first sub-block B21 and a second sub-block B22, the first sub-block B21 and the second sub-block B22 are spaced in the second direction Y, and the first sub-block B21 and the second sub-block B22 are connected by a first transparent wire. By providing the fourth sub-pixel B2 as two mutually connected sub-blocks, the diffraction peak intensity of the first display area AA1 can be further reduced, as shown in FIG. 6. In addition, the first sub-block B21 and the second sub-block B22 are connected by the first transparent wire 12, so that the influence of the connection wire connecting the first sub-block B21 and the second sub-block B22 on the light-transmitting area of the first display area AA1 can be avoided. For other descriptions, references are made to the above embodiments, and details are not described herein again.

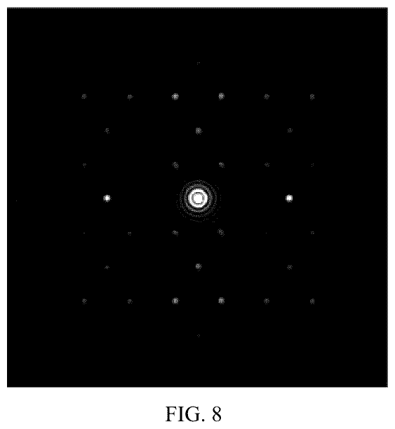

In an embodiment, referring to FIG. 1 to FIG. 8, FIG. 7 is another detailed structure diagram of the first pixel area provided in the embodiment of the present application, and FIG. 8 is a simulation diagram of diffraction peak intensity corresponding to the first pixel area in FIG. 7. Different from the above embodiment, in the first pixel area PA1, the shape of at least one of the fourth sub-pixel B2, the fifth sub-pixel R2, and the sixth sub-pixel G2 is a polygon, and the corners of the polygon are rounded. As shown in FIG. 7, the shapes of the fourth sub-pixel B2, the fifth sub-pixel R2, and the sixth sub-pixel G2 are all polygons, and the corners of the polygons are rounded. By providing the rounded corners for the fourth sub-pixel B2, the fifth sub-pixel R2, and the sixth sub-pixel G2 in the first pixel area PA1, the diffraction peak intensity of the first display area AA1 can be further reduced, as shown in FIG. 8. For other descriptions, references are made to the above embodiments, and details are not described herein again.

Based on the same inventive concept, an embodiment of the present application further provides an electronic device, wherein the electronic device includes a housing and a display panel described above, and the display panel is assembled in the housing. The electronic device includes a displayable product such as a mobile phone, a tablet, a television, a wearable display device, and the like.

According to the above embodiments, the following can be seen.

The present application provides a display panel and an electronic device. The display panel includes a first display area and a second display area at the periphery of the first display area. The first display area includes a plurality of first pixel areas and a plurality of pixel blank areas. Each of the pixel blank areas corresponds to three sub-pixel columns of the second display area, and each of the first pixel areas also corresponds to three sub-pixel columns of the second display area. In this way, the pixels of the first display area can be denser than the pixels of the second display area, so that the light transmittance of the first display area is greater than the light transmittance of the second display area, the light-transmitting area of the first display area can be increased, and the diffraction peak intensity can be reduced. As such, the imaging quality can be improved, thereby alleviating the technical problem that the imaging quality is reduced due to visible lights being diffracted by the area for the camera under panel.

As above, the description of each embodiment has its own emphasis, and the parts that are not described in detail in a certain embodiment can be referred to the related description of other embodiments.

The embodiments of the present application are described in detail above, and the principles and embodiments of the present application are described herein with specific examples. The description of the above embodiments is only used to help understand the technical solutions and core ideas of the present application. Those skilled in the art should understand that modifications can be made to the technical solutions described in the foregoing embodiments, or equivalent substitutions can be provided to some of the technical features thereof. These modifications or substitutions do not depart the essence of the corresponding technical solutions from the scope of the technical solutions of the embodiments of the present application.

1. A display panel, comprising a first display area and a second display area at a periphery of the first display area, wherein light transmittance of the first display area is greater than light transmittance of the second display area;
wherein the first display area includes a plurality of first pixel areas and a plurality of pixel blank areas, each of the plurality of first pixel areas and each of the plurality of pixel blank areas are alternately arranged in a first direction, the first pixel area and the pixel blank area are alternately arranged in a second direction, and the first direction and the second direction are different;
wherein the second display area comprises a plurality of sub-pixels arranged in an array, and the plurality of sub-pixels comprises a plurality of sub-pixel rows arranged in the first direction and a plurality of sub-pixel columns arranged in the second direction;
wherein in the first direction, the first pixel area overlaps two adjacent sub-pixel rows; and in the second direction, the first pixel area overlaps with three adjacent sub-pixel columns.

2. The display panel of claim 1, wherein in the second display area, the plurality of sub-pixels includes a plurality of first sub-pixels of a first color, a plurality of second sub-pixels of second color, and a plurality of third sub-pixels of third color;
wherein each of the plurality of first sub-pixels and each of the plurality of second sub-pixels are alternately arranged in the first direction to define a plurality of first rows, the plurality of third sub-pixels is arranged in the first direction to define a plurality of second rows, and the plurality of sub-pixel rows includes the plurality of first rows and the plurality of second rows alternately arranged;
wherein the first sub-pixel and the second sub-pixel are alternately arranged in the second direction to define a plurality of first columns, and the plurality of third sub-pixels are arranged in the second direction to define a plurality of second columns, and the plurality of sub-pixel columns includes the plurality of first columns and the plurality of second columns alternately arranged;
wherein in the first direction, the first pixel area overlaps one of the first rows and one of the second rows adjacent to the one of the first rows; and
in the second direction, the first pixel area overlaps one of the first columns and two of the second columns adjacent to the one of the first columns, or the first pixel area overlaps one of the second columns and two of the first columns adjacent to the one of the second columns.

3. The display panel of claim 2, wherein in the first display area, the first pixel area includes a plurality of fourth sub-pixels of the first color, a plurality of fifth sub-pixels of the second color, and a plurality of sixth sub-pixels of the third color;
wherein an area of each of the plurality of fourth sub-pixels is greater than an area of the first sub-pixel, an area of each of the plurality of fifth sub-pixel is greater than an area of the second sub-pixel, and an area of each of the plurality of sixth sub-pixels is greater than an area of the third sub-pixel.

4. The display panel of claim 3, wherein in the first direction, the fourth sub-pixel overlaps one of the first rows and one of the second rows adjacent to the one of the first rows, the fifth sub-pixel overlaps one of the first rows and the second rows adjacent, and the sixth sub-pixel overlaps another one of the first rows and the second rows adjacent; and
in the second direction, the fourth sub-pixel overlaps one of the first columns and one of the second columns adjacent to the one of the first columns, the fifth sub-pixel overlaps one of the first columns and one of the second columns adjacent to the one of the first columns, and the sixth sub-pixel overlaps one of the first columns and one of the second columns adjacent to the one of the first columns.

5. The display panel of claim 4, wherein in the first display area, the fourth sub-pixels are arranged in the second direction to define a plurality of third columns, and the fifth sub-pixel and the sixth sub-pixel are alternately arranged in the second direction to define a plurality of fourth columns;
wherein in the second direction, one of the third columns overlaps one of the first columns and one of the second columns adjacent to the one of the first columns, and one of the fourth columns overlaps one of the first columns and one of the second columns adjacent to the one of the first columns;
wherein in the second direction, one of the third columns and one of the fourth columns adjacent to the one of the third columns are overlapped with one of the first columns and two of the second columns adjacent to the one of the first columns, or overlapped with one of the second columns and two of the first columns adjacent to the one of the second columns.

6. The display panel of claim 5, wherein one of the third columns and one of the fourth columns adjacent to the one of the third columns share one data line with a corresponding one of the first columns and two of the second columns adjacent to the corresponding one of the first columns, or share one data line with a corresponding one of the second columns and two of the first columns adjacent to the corresponding one of the second columns.

7. The display panel of claim 6, wherein the fourth sub-pixel of the third column shares one data line with the first sub-pixel and the second sub-pixel of one of two adjacent first columns, the fifth sub-pixel of the fourth columns shares one data line with the first sub-pixel and the second sub-pixel of another one of the two adjacent first columns, and the sixth sub-pixel of the fourth column shares one data line with the third sub-pixel of the second column.

8. The display panel of claim 6, wherein the fourth sub-pixel of the third column shares one data line with the third sub-pixel of on of two adjacent second columns, the fifth sub-pixel of the fourth column shares one data line with the first sub-pixel and the second sub-pixel of the first column, and the sixth sub-pixel of each of the fourth columns shares one data line with each of the third sub-pixels of another one of the two adjacent second columns.

9. The display panel of claim 5, wherein in the first direction, one of the fourth sub-pixels overlaps one of the fifth sub-pixels and one of the sixth sub-pixels adjacent.

10. The display panel of claim 9, wherein the fourth sub-pixel includes a first sub-block and a second sub-block, the first sub-block and the second sub-block are spaced in the second direction, and the first sub-block and the second sub-block are connected by a first transparent wire.

11. The display panel of claim 9, wherein a shape of at least one of the fourth sub-pixel, the fifth sub-pixel, and the sixth sub-pixel is a polygon, and a corner of the polygon is rounded.

12. The display panel of claim 2, wherein the first color is blue, the third color is green, and the second color is red.

13. An electronic device, comprising a housing and a display panel mounted within the housing, the display panel comprising a first display area and a second display area located at the periphery of the first display area, a light transmittance of the first display area is greater than a light transmittance of the second display area;
Wherein the first display area includes a plurality of first pixel areas and a plurality of pixel blank areas, each of the plurality of first pixel area and each of the plurality of pixel blank areas are alternately arranged in a first direction, the first pixel area and the pixel blank area are alternately arranged in a second direction, and the first direction and the second direction are different;
wherein the second display area comprises a plurality of sub-pixels arranged in an array, and the plurality of sub-pixels comprises a plurality of sub-pixel rows arranged in the first direction and a plurality of sub-pixel columns arranged in the second direction;
wherein, in the first direction, the first pixel area overlaps two adjacent sub-pixel rows; and in the second direction, the first pixel area overlaps three adjacent sub-pixel columns.

14. The electronic device of claim 13, wherein in the second display area, the plurality of sub-pixels includes a plurality of first sub-pixels of a first color, a plurality of second sub-pixels of a second color, and a plurality of third sub-pixels of a third color;
wherein each of the plurality of first sub-pixels and each of the plurality of second sub-pixels are alternately arranged in the first direction to define a plurality of first rows, the plurality of third sub-pixels is arranged in the first direction to define a plurality of second rows, and the plurality of sub-pixel rows includes the plurality of first rows and the plurality of second rows alternately arranged;
wherein the first sub-pixel and the second sub-pixel are alternately arranged in the second direction to define a plurality of first columns, and the plurality of third sub-pixels are arranged in the second direction to define a plurality of second columns, and the plurality of sub-pixel columns includes the plurality of first columns and the plurality of second columns alternately arranged;
wherein in the first direction, the first pixel area overlaps one of the first rows and one of the second rows adjacent to the one of the first rows; and
in the second direction, the first pixel area overlaps one of the first columns and two of the second columns adjacent to the one of the first columns, or the first pixel area overlaps one of the second columns and two of the first columns adjacent to the one of the second columns.

15. The electronic device of claim 14, wherein in the first display area, the first pixel area includes a fourth sub-pixel of first color, a fifth sub-pixel of second color, and a sixth sub-pixel of third color;
wherein an area of the plurality of fourth sub-pixels is greater than an area of the first sub-pixel, an area of each of the plurality of fifth sub-pixel is greater than an area o of the second sub-pixel, and an area of each of the plurality of sixth sub-pixels is greater than an area of the third sub-pixels.

16. The electronic device of claim 15, wherein in the first direction, the fourth sub-pixel overlaps one of the first rows and one of the second rows adjacent to the one of the first rows, the fifth sub-pixel overlaps one of the first rows and the second rows, and the sixth sub-pixel overlaps another one of the first rows and the second rows;
in the second direction, the fourth sub-pixel overlaps one of the first columns and one of the second columns adjacent to the one of the first columns, the fifth sub-pixel overlaps one of the first columns and one of the second columns adjacent to the one of the first columns, and the sixth sub-pixel overlaps one of the first columns and one of the second columns adjacent to the one of the first columns.

17. The electronic device of claim 16, wherein in the first display area, the fourth sub-pixels are arranged in the second direction to define a plurality of third columns, and the fifth sub-pixel and the sixth sub-pixel are alternately arranged in the second direction to define a plurality of fourth columns;
wherein in the second direction, one of the third columns overlaps one of the first columns and one of the second columns adjacent to the one of the first columns, and one of the fourth columns overlaps one of the first columns and one of the second columns adjacent to the one of the first columns;
wherein in the second direction, one of the third columns and one of the fourth columns adjacent to the one of the third columns are overlapped with one of the first columns and two of the second columns adjacent to the one of the first columns, or overlapped with one of the second columns and two of the first columns adjacent to the one of the second columns.

18. The electronic device of claim 17, wherein one of the third columns and one of the fourth columns adjacent to the one of the third columns share one data line with a corresponding one of the first columns and two of the second columns adjacent to the corresponding one of the first columns, or share one data line with a corresponding one of the second columns and two of the first columns adjacent to the corresponding one of the second columns.

19. The electronic device of claim 18, wherein the fourth sub-pixel of the third column shares one data line with the first sub-pixel and the second sub-pixel of one of two adjacent first columns, the fifth sub-pixel of the fourth columns shares one data line with the first sub-pixel and the second sub-pixel of another one of the two adjacent first columns, and the sixth sub-pixel of the fourth column shares one data line with the third sub-pixel of the second column.

20. The electronic device of claim 18, wherein the fourth sub-pixel of the third column shares one data line with the third sub-pixel of on of two adjacent second columns, the fifth sub-pixel of the fourth column shares one data line with the first sub-pixel and the second sub-pixel of the first column, and the sixth sub-pixel of each of the fourth columns shares one data line with each of the third sub-pixels of another one of the two adjacent second columns.
